(19) United States
(12) Patent Application Publication
(10) Pub. No.: US 2018/0194052 A1
(43) Pub. Date: Jul. 12, 2018

(54) INVERTER COOLING METHOD FOR ELECTRIC INJECTION MOLDING MACHINE AND INVERTER COOLING DEVICE

(71) Applicant: THE JAPAN STEEL WORKS, LTD., Tokyo (JP)

(72) Inventor: Tomonori KAWAGUCHI, Hiroshima-shi, Hiroshima (JP)

(73) Assignee: THE JAPAN STEEL WORKS, LTD., Tokyo (JP)

(21) Appl. No.: 15/740,424

(22) PCT Filed: Jun. 30, 2016
(86) PCT No.: PCT/JP2016/069469

§ 371 Date: Dec. 28, 2017

(30) Foreign Application Priority Data
Jul. 10, 2015 (JP) 2015-138297

(51) Int. Cl. B29C 45/72; H01L 23/473; B29C 35/16

(52) U.S. Cl. CPC B29C 45/72; B29C 35/16; H01L 23/473

(57) ABSTRACT

An IGBT (6) forming an inverter (5a, 5b) that drives a brushless motor of an electric injection molding machine is attached to a cooling plate (2). A cooling liquid pipe (8) is provided in the cooling plate (2) to supply cooling liquid and cool the IGBT. The cooling liquid is supplied so as to be increased in an injection process. A plurality of sets of IGBTs (6) corresponding to a plurality of inverters (5a, 5b, 5c) are attached to the cooling plate (2), and the cooling liquid is circulated respectively in the vicinities of the plurality of sets of IGBTs (6).

### TECHNICAL FIELD

The present invention relates to a cooling method for an inverter which drives a motor such as a servomotor of an electric injection molding machine and a cooling device for an inverter.

### BACKGROUND ART

As well known, an injection molding machine includes a closing device which closes a die, an injection device which melts a resin to inject the resin to the closed die and an ejection device which ejects a molded product from the die. In the electric injection molding machine, these devices are respectively driven by a brushless motor such as a servomotor. In the electric injection molding machine, a converter is provided in which a three-phase AC voltage supplied from an external part is rectified to a DC voltage. Then, the DC voltage is converted to the thee-phase AC voltage by an inverter provided for each brushless motor to drive the brushless motor. The inverter which drives the servomotor is also referred to as a servo-amplifier.

The inverter is formed with a power transistor such as an IGBT (Insulated Gate Bipolar Transistor: Insulating Gate Bipolar Transistor) and its temperature becomes high by heating. The power transistor is provided under a state that a semiconductor element is accommodated in a package. When a temperature of a connection part of the semiconductor element therein, namely, a junction temperature is high, a life of the power transistor is shortened. For instance, when the junction temperature becomes such a temperature as high as 175° C., the power transistor is broken. Accordingly, in a usual inverter, the power transistor such as the IGBT is attached to a cooling plate having heat radiating fins so as to be forcibly air cooled by supplied air from a cooling fan. Thus, the junction temperature is suppressed to be, for instance, 120° C. or lower.

### CITATION LIST

### Patent Literature

Patent Literature 1: JP-A-2006-177601

The patent literature 1 discloses a servo-amplifier of an electric injection molding machine which is water cooled. In the servo-amplifier disclosed in the patent literature 1, an IGBT is attached to a metallic cooling plate having therein a cooling pipe provided in which cooling liquid flows. The cooling liquid supplied to the cooling plate is fed to be circulated by a prescribed pressure pump. Further, the cooling liquid is cooled by a heat pump. Since the servo-amplifier is forcibly cooled by the cooling liquid having a thermal capacity larger than that of air, the rise of temperature of the IGBT can be assuredly suppressed.

Further, in the servo-amplifier disclosed in the patent literature 1, the heat pump is controlled in such a way that the temperature of the circulating cooling liquid is located within 5° C. relative to an ambient temperature in the vicinity of the cooling plate. Accordingly, the servo-amplifier can be safely cooled without a concern of vapor condensation due to an excessive cooling.

In the device disclosed in the patent literature 1, the plurality of servo-amplifiers provided respectively for the servomotors are provided in the plurality of cooling plates. Accordingly, the cooling liquid is supplied in parallel to the plurality of cooling plates.

### SUMMARY OF INVENTION

### Technical Problem

When the inverter is cooled by air cooling as in the usual inverter, or when the inverter is cooled by water cooling as disclosed in the patent literature 1, the inverter can be cooled to protect the IGBT. However, problems that are to be solved are found respectively.

Initially, in the usual method for cooling the inverter by air cooling, it may be said that a problem resides in a point that a cooling efficiency is low. In recent years, an output required for the electric injection molding machine is increased. Accordingly, in order to drive a large servomotor, an inverter having a large capacity is necessary. In such an inverter, a current in the IGBT is large and a heat generation rate is large. Since the air is low in its thermal capacity, the inverter cannot be satisfactorily cooled by an air cooling type. There is a fear that the junction temperature may exceed an allowable value. Further, a problem is also found in view of a point that the cooling fan is necessary in the air cooling type. The cooling fan generates large noise and raises dust to contaminate an ambient environment therewith.

As compared with the usual cooling method by the air cooling type, in the method for cooling the inverter by the water cooling type disclosed in the patent literature 1, since the cooling fan is not necessary and the inverter is cooled by the cooling liquid having the thermal capacity larger than that of the air, it may be said that the cooling efficiency is high, and accordingly, the method is excellent. However, in the water cooling method disclosed in the patent literature 1, there is also found room for improvement. Specifically, there is room for longer life of the IGBT and reduction of energy required for cooling.

When the IGBT cooled by the water cooling method is driven, the junction temperature rises, and when the IGBT is driven to stop, the junction temperature rapidly falls. When a difference between the upper junction temperature and the lower junction temperature is large, this difference gives an influence to the life of the IGBT. In the inverter disclosed in the patent literature 1, the cooling plate is constantly cooled by the pressure pump. However, when the IGBT is forcibly cooled in such a way, the ordinary junction temperature of the IGBT is considerably low. In the inverter disclosed in the patent literature 1, the cooling liquid is supplied in parallel to the plurality of cooling plates. This fact also causes the junction temperature of the IGBT to be considerably low. Namely, although the inverters are respectively driven to generate heat only when the corresponding motors are driven, the cooling plate of the inverter which has no relation to the driving is unnecessarily cooled. Accordingly, the junction temperature of the IGBT is fairly low. When the IGBT is driven from such a state that the junction temperature of the IGBT is considerably low, a change of the junction temperature is large. Thus, the life of the IGBT is affected thereby.

For the reduction of the energy required for cooling, problems reside in the points that the pressure pump is constantly driven and the cooling liquid is supplied in parallel to the plurality of cooling plates. Originally, the IGBT may be cooled only when the temperature of the IGBT is high. Thus, it may be considered that the energy required for cooling can be reduced. Further, when the cooling liquid is supplied in parallel to the plurality of cooling plates, a pump of a large capacity is necessary. Thus, it may be considered that the energy is wasted. However, a consideration concerning such points is not disclosed in the patent literature 1.

It is an object of the present invention to provide a cooling method for an inverter and a cooling device for an inverter for an electric injection molding machine which solve the above-described problems. Specifically, it is an object of the present invention to provide a cooling method for an inverter and a cooling device for an inverter for an electric injection molding machine in which a life of a power transistor such as an IGBT can be lengthened as long as possible and an energy cost required for cooling is low.

### Solution to Problem

In order to achieve the object of the present invention, the present invention is formed as a method for cooling an inverter which drives a brushless motor of an electric injection molding machine. A power transistor forming the inverter is attached to a prescribed cooling plate. A cooling liquid pipe is provided in the cooling plate to supply cooling liquid and cool the power transistor. The cooling liquid is designed so as to change a flow rate to be supplied synchronously with a molding cycle of an injection molding. Further, a plurality of sets of power transistors corresponding to a plurality of inverters is attached to the cooling plate. The cooling liquid is designed to be circulated in the vicinity of the plurality of sets of power transistors.

The above-described object is achieved by below-described structures.

(1) A cooling method for an inverter of an electric injection molding machine, comprising: cooling the inverter that is configured to drive a brushless motor of the electric injection molding machine, wherein the inverter is attached to a prescribed cooling plate in which power transistor forming the inverter is cooled by cooling liquid; and changing a flow rate of supply of the cooling liquid synchronously with a molding cycle of an injection molding.

(2) The cooling method for an inverter of an electric injection molding machine according to the above (1), wherein a plurality of sets of power transistors corresponding to a plurality of inverters are attached to the cooling plate, and wherein the cooling liquid is circulated in the vicinities of the plurality of sets of power transistors.

(3) A cooling device for an inverter of an electric injection molding machine for cooling the inverter that is configured to drive a brushless motor of the electric injection molding machine, the inverter cooling device comprising: a cooling plate, to which a power transistor forming the inverter is attached; and a pump configured to supply cooling liquid to a cooling liquid pipe formed in the cooling plate, wherein the pump is driven by an inverter controlled motor and is configured such that a flow rate of the cooling liquid is changed synchronously with a molding cycle of an injection molding.

(4) The cooling device for an inverter of an electric injection molding machine according to the above (3), wherein a plurality of sets of power transistors corresponding to a plurality of inverters are attached to the cooling plate, and wherein the cooling liquid pipe is circulated respectively in the vicinities of the plurality of sets of power transistors.

### Advantageous Effects of Invention

As described above, the present invention relates to the method for cooling the inverter which drives the brushless motor of the electric injection molding machine. In the inverter, the power transistor forming the inverter is attached to the prescribed cooling plate in which the power transistor is cooled by the cooling liquid. The cooling liquid is designed so as to change the flow rate to be supplied synchronously with the molding cycle of the injection molding. Thus, initially, since the inverter is cooled by the water cooling type, the cooling efficiency is high, and a large rise of the junction temperature of the power transistor such as the IGBT can be assuredly suppressed. Thus, the life of the power transistor such as the IGBT can be lengthened. Further, since the cooling efficiency is high, a cooling device can be made to be small and a cost can be reduced.

A plurality of brushless motors such as servomotors is provided in the electric injection molding machine. However, the brushless motors are partly driven in each of processes of the molding cycle, and other brushless motors are stopped. The brushless motor which requires an output higher than that of other motor is a servomotor for injection used in an injection process. It may be said to be a servo-amplifier which drives the brushless motor, namely, the inverter that has a large heat generation rate.

According to the present invention, the cooling liquid is designed so as to change the flow rate to be supplied synchronously with the molding cycle of the injection molding. Thus, the flow rate of the cooling liquid can be finely controlled in accordance with the heat generation rate. Specifically, in the injection process, the flow rate of the cooling liquid is increased so as to meet the heat generation rate. In such a way, the inverter can be cooled only at a necessary time and the power transistor can be prevented from being excessively cooled. Thus, a change of the junction temperature can be more reduced, and the life of the power transistor can be lengthened. Further, a cost required for cooling can be lowered.

According to another invention, the plurality of sets of power transistors corresponding to the plurality of inverters is attached to the cooling plates. The cooling liquid is designed to be circulated in the vicinities of the plurality of sets of power transistors. As described above, since the plurality of brushless motors provide in the electric injection molding machine are used only in a part of the respective processes of the molding cycle, when an entire part of the molding cycle is seen, the number of the brushless motors driven at the same time is small. Thus, the number of the inverters driven at the same time is also small. According to the present invention, since the plurality of sets of power transistors are provided in the cooling plates and the cooling liquid is circulated therein, it may be said that the plurality of inverters are cooled at the same time. Thus, the cooling liquid may be reduced and the small cooling device can be provided at low cost.

### BRIEF DESCRIPTION OF DRAWINGS

FIG. 1 is a diagram showing a cooling device for an inverter of an electric injection molding machine according to an embodiment of the present invention, in which FIG. 1(a), FIG. 1(b) and FIG. 1(c) are respectively a front view, a side view and a front sectional view of a cooling plate to which plurality of sets of IGBTs of inverters are attached, according to an embodiment of the present invention, and FIG. 1(d) is a front view of the cooling device for the inverter according to the embodiment.

FIG. 2 is a graph showing a consumption electric power changing in a molding cycle and a quantity of supply of cooling liquid of the cooling device for the inverter according to the embodiment of the present invention.

FIG. 3 is a graph showing a change of a junction temperature of an IGBT when the IGBT is driven and a change of a temperature of a case in which the IGBT is accommodated.

### DESCRIPTION OF EMBODIMENTS

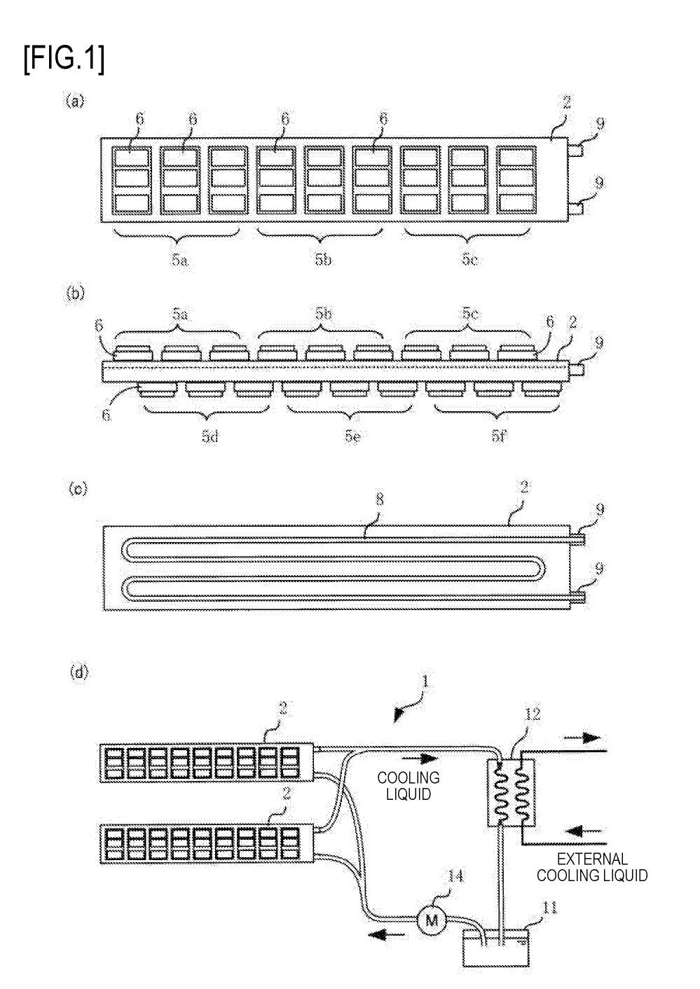

Now, an embodiment of the present invention will be described below. An electric injection molding machine according to the present embodiment is designed to be driven by a plurality of brushless motors such as servomotors like a usual electric injection molding machine. These brushless motors are driven by a three-phase AC voltage generated by an inverter. In the electric injection molding machine according to the present embodiment, the inverter is provided in an inverter cooling device according to the present embodiment. As described below in detail, the inverter cooling device 1 includes two cooling plates 2 and 2 as shown in FIG. 1(d). Features of the inverter cooling device 1 resides in a water cooling type, a control method for supplying cooling liquid to the cooling plates 2 and 2, the form of the cooling plate 2 and an arrangement of the inverters.

Initially, the cooling plate 2 will be described below. The cooling plate 2 is formed with metal excellent in its thermal conductivity such as aluminum, and formed in a rectangular shape having long sides and a prescribed thickness as shown in FIG. 1(a) and FIG. 1(b). In a usual inverter, three IGBTs forming one inverter are attached to a prescribed cooling plate as one set. As compared therewith, in the present embodiment, for one cooling plate 2, six sets of IGBTs 6, 6 . . . , namely, 18 IGBTs 6, 6 . . . corresponding to six inverters 5a, 5b . . . are attached to a front surface and a back surface thereof. Namely, the present embodiment is characterized in that a relatively large number of inverters 5a, 5b . . . are attached to the one cooling plate 2. In order to cool the IGBTs 6, 6, in the cooling plate 2, a cooling liquid pipe 8 is provided so as to circulate cooling liquid as shown in FIG. 1(c).

In the present embodiment, the cooling liquid pipe 8 makes two reciprocations in the direction of a long side of the cooling plate 2. Pipeline terminals 9 and 9 as an outlet and an inlet of the cooling liquid pipe 8 are provided in one short side of the cooling plate 2. The cooling liquid is made of water to which an anti-corrosive agent and an anti-freezing agent or the like is added. Since the cooling liquid is liquid, the cooling liquid has a large thermal capacity. Accordingly, even when the cooling plate 2 has a large number of IGBTs 6, 6 . . . provided, the cooling plate 2 can efficiently cool them. Then, all the IGBTs 6, 6 . . . can be equally cooled by the cooling liquid pipe 8 which makes two reciprocations in the direction of the long side.

The inverter cooling device 1 according to the present embodiment includes: the above-described two cooling plates 2 and 2; a reserve tank 11 which stores a prescribed quantity of cooling liquid; a pump 14 which supplies the cooling liquid of the reserve tank 11 to the cooling plates 2 and 2; a heat exchanger 12 in which the cooling liquid with its temperature raised that is returned from the cooling plates 2 and 2 is cooled; and a cooling liquid circulation pipeline which connects the reserve tank 11, the pump 14, the cooling plates 2 and 2 and the heat exchanger 12 together to circulate the cooling liquid.

To the heat exchanger 12, external cooling liquid which is supplied from an external part is supplied so as to exchange heat with the cooling liquid. The cooling liquid in the reserve tank 11 is maintained to a prescribed temperature range by the heat exchange in the heat exchanger 12. Since such a structure is provided, when the pump 14 is driven, the cooling liquid is circulated, so that the cooling plates 2 and 2 can be cooled to cool the inverters 5a, 5b . . . .

In the present embodiment, the pump 14 is driven by an inverter controlled motor. Accordingly, when a rotational speed of the motor is changed, a quantity of supply of the cooling liquid can be changed.

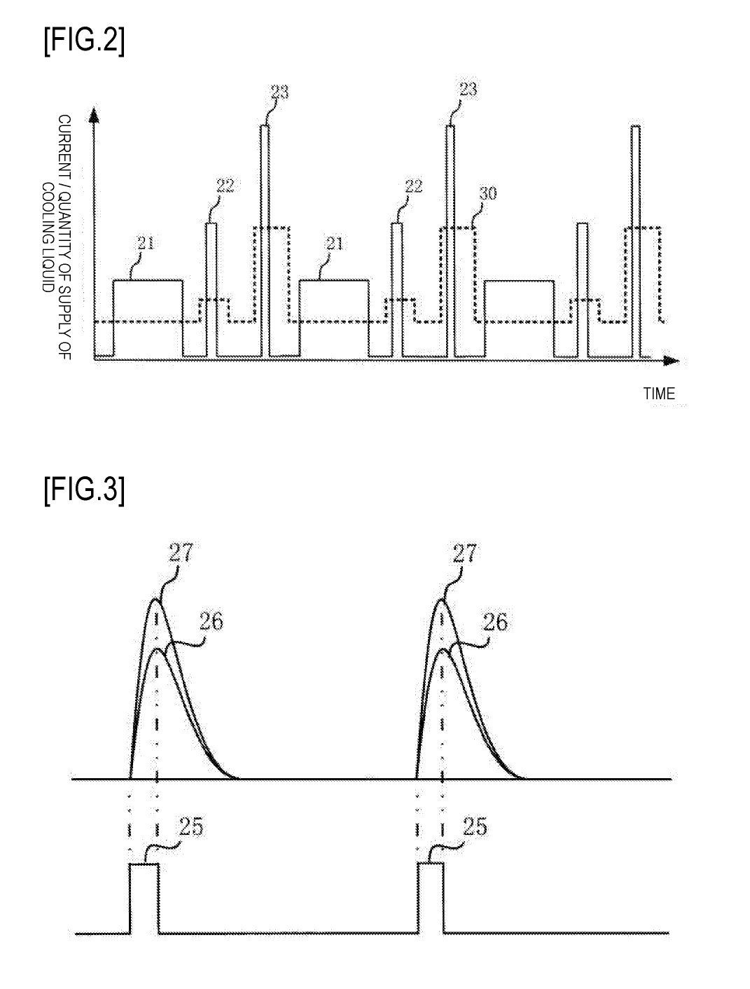

Now, an operation method of the inverter cooling device 1 according to the present embodiment will be described below. When a molding cycle of an injection molding is carried out in the electric injection molding machine, since the inverter is driven to rotate a prescribed brushless motor in each of processes, a current in the inverter is changed. Although an actual change of the current is complicated, FIG. 2 shows a graph schematically illustrating a rough change of the current. In the molding process, since a plasticizing motor is driven for a relatively long time as shown reference numeral 21 in a metering process, the current is stabilized to a prescribed value. In a die opening and closing process, a slightly high current is supplied for a short time as shown by reference numeral 22. Then, in an injection process, a high current is supplied for a short time as shown by reference numeral 23.

As shown in FIG. 3, when the inverter is driven as shown by reference numeral 25, in the IGBT forming the inverter, a temperature rises. When the driving is stopped, the temperature falls. More specifically described, the temperature of a package of the IGBT changes as shown by reference numeral 26 and a junction temperature changes as shown by reference numeral 27. The magnitude of the current in the inverter is changed depending on a driving time of the inverter and also affects the rise of the temperature of the IGBT. Accordingly, a degree of the rise of the temperature of the IGBT in the injection process 23 is larger than that of the metering process 21.

Since a degree of a difference of the change of the junction temperature gives an influence to the life of the IGBT, the inverter is desired to be cooled in such a way that the difference of the change of the temperature is small. Further, when an excessively large cooling capacity is not required, a cost required for cooling is desired to be lowered. Thus, in the present embodiment, the quantity of the cooling liquid supplied to the cooling plates 2 and 2 in the inverter cooling device 1 is devised to be changed synchronously with the molding cycle, so that the quantity of supply of the cooling liquid is maximum at least in the injection process 23 in which the current in the inverter is the largest.

A graph shown by reference numeral 30 in FIG. 2 shows one example of such a change of the quantity of supply of the cooling liquid. As a whole including the metering process 21, the quantity of supply of the cooling liquid is designed to be set to a prescribed quantity of supply of the cooling liquid, to a slightly larger quantity of supply of the cooling liquid in the die opening and closing process and to the largest quantity of supply of the cooling liquid in injection process 23. In such an operation, the change of the junction temperature of the IGBT is reduced and the life of the IGBT is lengthened. Thus, the cost required for cooling can be suppressed.

The present invention is not limited to the above-described embodiment and may be suitably and freely modified or improved. In addition thereto, materials, dimensions, values, forms, numbers, arranged positions or the like of the component elements in the above-described embodiment are arbitrary and are not limited as long as the present invention can be achieved.

The present invention is specifically described in detail by referring to the specific embodiment, however, it is to be understood to a person with ordinary skill in the art that various changes or modification may be made without departing from the spirit and scope of the present invention.

This application is based on Japanese Patent Application (Japanese Patent Application No. 2015-138297) filed on Jul. 10, 2015 and contents thereof are incorporated herein as a reference.

Here, features of the embodiment of the cooling method for the inverter and the cooling device for the inverter of the electric injection molding machine according to the above-described present invention are briefly summarized and respectively listed in the following [1] to [4].

[1] A cooling method for an inverter of an electric injection molding machine, including: cooling the inverter (5a to 5f) that is configured to drive a brushless motor of the electric injection molding machine, wherein the inverter (5a to 5f) is attached to a prescribed cooling plate (2) in which a power transistor (IGBT 6) forming the inverter (5a to 5f) is cooled by cooling liquid; and changing a flow rate of supply of the cooling liquid synchronously with a molding cycle of an injection molding.

[2] The cooling method for an inverter of an electric injection molding machine according to the above-described [1], wherein a plurality of sets of power transistors (IGBT 6) corresponding to a plurality of inverters (5a to 5f) are attached to the cooling plate (2), and the cooling liquid is circulated in the vicinities of the plurality of sets of power transistors.

[3] A cooling device (1) for an inverter of an electric injection molding machine for cooling the inverter (5a to 5f) that is configured to drive a brushless motor of the electric injection molding machine, the inverter cooling device (1) including: a cooling plate (2), to which a power transistor (IGBT 6) forming the inverter (5a to 5f) is attached; and a pump (14) configured to supply cooling liquid to a cooling liquid pipe (8) formed in the cooling plate (2), wherein the pump (14) is driven by an inverter controlled motor and is configured such that a flow rate of the cooling liquid is changed synchronously with a molding cycle of an injection molding.

[4] The cooling device (1) for an inverter of an electric injection molding machine according to the above-described [3], wherein a plurality of sets of power transistors (IGBT 6) corresponding to a plurality of inverters (5a to 5f) are attached to the cooling plate (2), and wherein the cooling liquid pipe (8) is circulated respectively in the vicinities of the plurality of sets of power transistors (IGBT 6).

### INDUSTRIAL APPLICABILITY

According to the present invention, the cooling method for the inverter and the cooling device for the inverter of the electric injection molding machine can be provided in which the life of the power transistor such as the IGBT can be extended as long as possible and an energy cost required for cooling is low. The present invention which realizes the above-described effects is available for the field of a cooling method for an inverter and a cooling device for an inverter of an electric injection molding machine.

### REFERENCE SIGNS LIST

1 Inverter cooling device

1 Cooling plate

5a, 5b, 5c Inverter

6 IGBT

8 Cooling liquid pipe

11 Reserve tank

12 Heat exchanger

14 Pump

1. A cooling method for an inverter of an electric injection molding machine, comprising:
cooling the inverter that is configured to drive a brushless motor of the electric injection molding machine, wherein the inverter is attached to a prescribed cooling plate in which power transistor forming the inverter is cooled by cooling liquid; and
changing a flow rate of supply of the cooling liquid synchronously with a molding cycle of an injection molding.

2. The cooling method for an inverter of an electric injection molding machine according to claim 1, wherein a plurality of sets of power transistors corresponding to a plurality of inverters are attached to the cooling plate, and wherein the cooling liquid is circulated in the vicinities of the plurality of sets of power transistors.

3. A cooling device for an inverter of an electric injection molding machine for cooling the inverter that is configured to drive a brushless motor of the electric injection molding machine, the inverter cooling device comprising:
a cooling plate, to which a power transistor forming the inverter is attached; and
a pump configured to supply cooling liquid to a cooling liquid pipe formed in the cooling plate,
wherein the pump is driven by an inverter controlled motor and is configured such that a flow rate of the cooling liquid is changed synchronously with a molding cycle of an injection molding.

4. The cooling device for an inverter of an electric injection molding machine according to claim 3, wherein a plurality of sets of power transistors corresponding to a plurality of inverters are attached to the cooling plate, and wherein the cooling liquid pipe is arranged such that the cooling liquid is circulated respectively in the vicinities of the plurality of sets of power transistors.
